(19) United States
(12) Patent Application Publication
(10) Pub. No.: US 2004/0232536 A1
(43) Pub. Date: Nov. 25, 2004

(54) Semiconductor device comprising magnetic element

(76) Inventor: Yoshiaki Fukuzumi, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/649,731

(22) Filed: Aug. 28, 2003

(30) Foreign Application Priority Data
May 22, 2003 (JP) 2003-144917

(51) Int. Cl. H01L 21/44

(52) U.S. Cl. 257/684; 257/678

(57) ABSTRACT

A semiconductor device includes a semiconductor chip provided with a magnetic element, and an enclosure which seals the magnetic chip. Substantially spherical magnetic substance particles are interspersed in the enclosure.

### CROSS-REFERENCE TO RELATED APPLICATIONS

This application is based upon and claims the benefit of priority from the prior Japanese Patent Application No. 2003-144917, filed May 22, 2003, the entire contents of which are incorporated herein by reference.

### BACKGROUND OF THE INVENTION

1. Field of the Invention

The present invention relates to a semiconductor device comprising a magnetic element, for example, a magnetic random access memory.

2. Description of the Related Art

A magnetic random access memory (hereinafter referred to as an “MRAM”) is a generic term for solid state memories acting as recorded information carriers that utilize the axis of magnetization of a ferro-magnetic substance to enable recorded information to be rewritten, retained, or read as required.

A memory cell in an MRAM normally has a structure in which a plurality of ferromagnetic substances are stacked. Information is recorded in the memory cell by associating the relative arrangement of magnetizations of the plurality of ferromagnetic substances constituting the memory cell, with binary information so that the parallel or antiparallel relative arrangement corresponds to “1” or “0”. Information is written by reversing the axes of magnetization of the ferromagnetic substances in each cell using galvanomagnetic fields generated by conducting a current through write lines arranged in cross stripe form. In this nonvolatile memory, in principle, no power is consumed while recorded information is retained, and recorded information is retained even after a power supply is turned off. Recorded information is read utilizing what is called a “magnetic resistance effect”, a phenomenon in which the electric resistance of the memory cell varies depending on the relative angle between the axes of magnetization of the ferromagnetic substances constituting the cell and a sense current, or the relative angle between the magnetizations of a plurality of ferromagnetic layers.

The MRAM has a large number of functional advantages compared to a conventional semiconductor memory that use dielectrics, as described below.

(1) The MRAM is perfectly nonvolatile and enables information to be rewritten 10¹⁵ times or more.

(2) The MRAM enables recorded information to be read nondestructively to eliminate the need for refresh operations, thus shortening read cycles. (3) The MRAM can endure radiation better than charge-storage memory cells. The MRAM is expected to be equivalent to DRAMs in terms of the degree of integration per unit area and write and read times. Accordingly, on the basis of its major characteristic, non-volatility, the MRAM is expected to be applied to external storage devices for portable equipment, to mixed LSIs, and to main storage memories in personal computers.

However, if MRAMs are manufactured using a conventional packaging technique, the problems described below arise. Owing to the recent increase in density in packaging techniques, in an environment in which the MRAM is actually used, power lines or the like may have to pass by elements. Then, possible leakage magnetic fields may destroy data stored in, for example, MTJ (Magnetic Tunnel Junction) elements.

Further, switching magnetic fields for the MRAM are about 50 [Oe] (oersted) in intensity. Magnetic fields of higher intensities are often encountered in everyday life. For example, such magnetic fields are generated by telephone receivers.

Accordingly, certain magnetic shield measures must be taken to protect the MRAM from these magnetic fields. For this purpose, arrangements have been proposed in which, for example, after a packaging step, an MRAM product is covered with a box of a magnetic substance, i.e. a plate made of NiFe, or the like. However, these arrangements tend to complicate the packaging technique or increase costs.

Alternatively, an MRAM chip (die) can be covered with a box of a magnetic substance (a plate made of NiFe, or the like) such as that described above, in the packaging step. However, it is difficult to avoid complicating the packaging step or increasing costs.

Furthermore, different magnetic shield measures have been proposed which are carried out during the packaging step utilizing a powdered magnetic substance (for example, U.S. Pat. No. 6,429,044). The technique described in this patent document attempts to simplify a manufacturing process and reduce costs by interspersing a powdered magnetic substance in a package. However, the magnetic shape anisotropy of the interspersed powders may contribute to fixing the orientations of spins to a specific direction or creating areas that insufficiently shield magnetic fields. Thus, an intended sufficient magnetic shield effect is not always produced.

### BRIEF SUMMARY OF THE INVENTION

According to an aspect of the present invention, there is provided a semiconductor device comprising a semiconductor chip comprising a magnetic element, an enclosure which seals the magnetic chip, and substantially spherical magnetic substance particles which are interspersed in the enclosure.

According to an aspect of the present invention, there is provided a semiconductor device comprising, a semiconductor chip comprising a magnetic element, an enclosure which seals the magnetic chip and which has a base material and a cap material joined together via a sealing material, a magnetic film provided on a chip side surface of the base material and on an inner surface of the cap material so as to surround the semiconductor chip.

### BRIEF DESCRIPTION OF THE SEVERAL VIEWS OF THE DRAWING

FIG. 1 is a sectional view illustrating a semiconductor device according to a first embodiment of the present invention, the view schematically showing an example in which an MRAM is sealed in a plastic package;

FIG. 2 is a sectional view illustrating a variation of the first embodiment of the present invention, the view schematically showing an example in which an MRAM is sealed in a plastic package;

FIG. 3 is a sectional view illustrating a semiconductor device according to a second embodiment of the present invention, the view schematically showing an example in which an MRAM is sealed in a plastic package;

FIG. 4 is a sectional view illustrating a variation of the second embodiment of the present invention, the view schematically showing an example in which an MRAM is sealed in a plastic package;

FIG. 5 is a sectional view illustrating another variation of the second embodiment of the present invention, the view schematically showing an example in which an MRAM is sealed in a plastic package; and

FIG. 6 is a sectional view illustrating another variation of the second embodiment of the present invention, the view schematically showing an example in which an MRAM is sealed in a plastic package.

### DETAILED DESCRIPTION OF THE INVENTION

Embodiments of the present invention will be described below with reference to the drawings. In this description, common parts are denoted by common reference numerals throughout the drawings.

[First Embodiment]

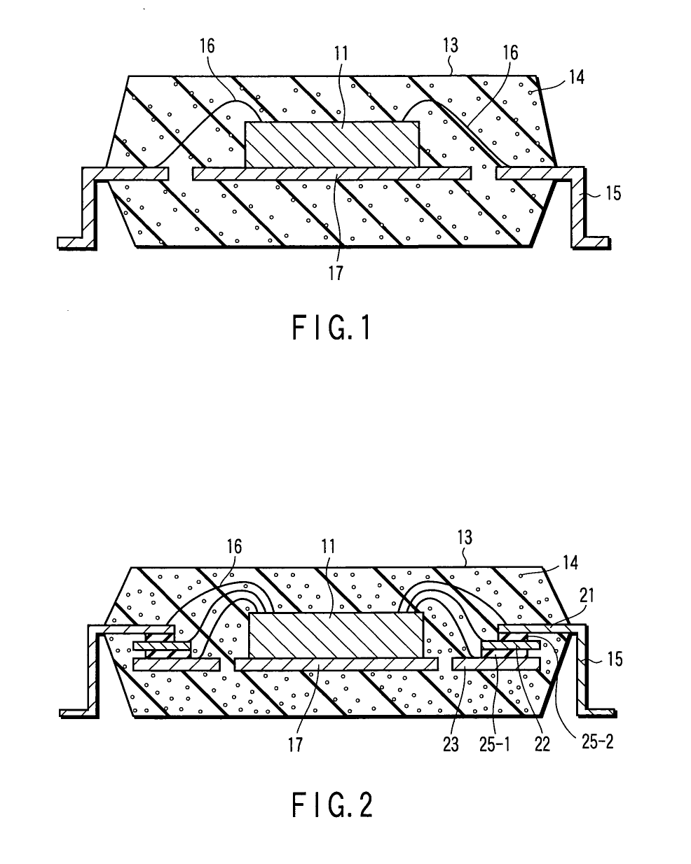

FIG. 1 is a sectional view illustrating a semiconductor device according to a first embodiment of the present invention, the view schematically showing an example in which an MRAM is sealed in a plastic package (enclosure).

As shown in FIG. 1, a die pad 17 is arranged inside an inner lead portion of a lead frame 15. A semiconductor chip 11 is mounted on the die pad 17 by die bonding. A magnetic element is formed in the semiconductor chip 11 by stacking a plurality of ferromagnetic substances (not shown). Bonding wires 16 are used to electrically connect the inner lead portion of the lead frame 15 and an external connection electrode (pad) of the semiconductor chip 11 together. The semiconductor chip 11, the die pad 17, the bonding wires 16, and the inner lead portion of the lead frame 15 are each sealed by a plastic package 13.

The package 13 is molded using, for example, a biphenyl-based epoxy resin or a silicone resin. Magnetic substance particles 14 are interspersed in the package 13. A material for the magnetic substance particles 14 contain, for example, a ferrite (MFe₂O₄, where M=one of Mn, Fe, Co, Ni, Cu, Mg, and ZnLi_{0.5}Fe_{0.5}). Desirably, the magnetic substance particles 14 are substantially spherical and each have a diameter of about 20 μm or less. Furthermore, the magnetic substance particles 14 interspersed in the package 13 desirably amount to 1 wt % or more of the total weight of the package 13.

For example, an MTJ element is used as the magnetic element. In general, an MTJ element is formed at the intersection between a first write interconnect and a second write interconnect. The MTJ element is formed of a free layer in which the orientations of spins are variable, a tunnel barrier layer provided adjacent to the free layer, a pin layer provided adjacent to the tunnel barrier layer, and a fixing layer provided adjacent to the pin layer and in which the orientations of spins in the pin layer are fixed. The free layer and the pin layer are formed of a ferromagnetic substance. The tunnel barrier layer is formed of a non-ferromagnetic substance. The ferromagnetic substance may be, for example, a transition metal magnetic element (Fe, Co, Ni, etc.) or its alloy (for example, CoFe, CoFeNi, or NiFe). Further, the fixed layer is formed of an antiferro-magnetic substance (for example, FeMn, IrMn, or PtMn).

A read operation is performed on the MTJ element by sequentially conducting a current through the free layer, the tunnel barrier layer, the pin layer, and the fixing layer and then amplifying and detecting resistance values. Another tunnel magneto-resistance element, for example, a GMR (Giant Magnetoresistance) element, can also be used.

As described above, the magnetic substance particles 14 are interspersed in the package 13. Thus, external leakage magnetic fields and the like are absorbed by the magnetic substance particles 14. Few of such magnetic fields are applied to the magnetic element in the semiconductor chip 11. As a result, it is possible to effectively block magnetic fields that may cause the magnetic element to malfunction.

Further, if the magnetic substance particles are untreated shape (for example, immediately after crushing) and each have concaves and convexes on their surfaces, their magnetic shape anisotropy causes the orientations of spins to be easily fixed to a specific direction. This reduces the magnetic shield effect on external magnetic fields or the like. However, the magnetic substance particles 14 are substantially spherical. Thus, the magnetic shape anisotropy is not exhibited, and the orientations of spins can be easily varied depending on external leakage magnetic fields. As a result, a magnetic shield effect can be produced using a reduced amount of magnetic substance particles 14. It is thus possible to reduce the cost of products such as MRAMs, and improve their reliability.

Here, the spacing between bonding pads on a normal semiconductor chip is, for example, about 100 μm. Further, their diameter is, for example, 20 to 30 μm. Thus, if the magnetic substance particles 14 are excessively large, defects may occur; a resin may be inappropriately injected when the package 13 is formed or the bonding wires 16 may be cut. However, these defects can be avoided by setting the diameter of each magnetic substance particle 14 at about 20 μm or less.

Furthermore, if the typical package 13 has a film thickness of, for example, about 1 mm and the magnetic substance particle 14 has a diameter of, for example, about 10 μm, the minimum concentration required to populate one magnetic substance particle 14 in the direction of the film thickness can be expressed in terms of volume percentage as follows: {(4/3)×π×(10/2)²}/{π×(10/2)²×1000}=0.67[%]. A precondition for this equation is that the magnetic substance particle 14 has a higher specific gravity than the resin constituting the package 13. Thus, when the package 13 contains 1 wt % or more of interspersed magnetic substance particles 14, it is possible to prevent the creation of areas having an insufficient magnetic shield effect on external leakage magnetic fields or the like. By thus estimating, to some degree, the amount of magnetic substance particles mixed into the package 13, it is possible to reduce the cost of products such as MRAMs, and improve their reliability.

Furthermore, if the plastic package 13 is used, as in the case with the present embodiment, the semiconductor chip 11 can be covered with the integrally molded package 13 which is almost continuous in its longitudinal and transverse directions except for the lead-out portion of the lead frame 15. This makes it possible to effectively block external-magnetic fields.

The material for the package 13 may be a resin other than the above described biphenyl-based epoxy resin or silicone resin.

Further, the magnetic substance particles 14 may be composed of an oxide magnetic substance other than a ferrite, such as a spinel oxide magnetic substance (for example, chromite), a garnet oxide magnetic substance, or a perovskite oxide magnetic substance. Further, the magnetic substance particles 14 are desirably insulators. However, they may be conductive as long as the package 13 can be insulated.

[Variation 1]

Next, with reference to FIG. 2, description will be given of a variation of the semiconductor device according to the first embodiment. FIG. 2 is a sectional view schematically showing that an MRAM is sealed in a plastic package. In this variation, only differences from the first embodiment will be described. The other points are similar to those of the first embodiment. Thus, their detailed description is omitted.

As shown in FIG. 2, the inner lead portion of the lead frame 15 has a structure in which a plurality of conductive and insulating layers are stacked. Furthermore, the bonding wires 16, connected to the semiconductor chip 11, are selectively connected to a first-conductive layer 23, a second conductive-layer 22, and a third conductive layer 21. Insulating layers 25-1 and 25-2 are interposed between the first conductive layer 23 and the second conductive layer 22 and between the second conductive layer 22 and the third conductive layer 21 for electric insulation. Moreover, a through-hole is formed through the insulating layers 25-1 and 25-2. The first conductive layer 23 and the second conductive layer 22 are selectively connected to the third conductive layer 21 via a conductive material buried in the through-hole. The third conductive layer 21 is then led out to an outer lead portion (not shown).

This structure basically produces effects similar to those of the first embodiment.

Further, the inner lead portion of the lead frame is multilayered as described above. Thus, even if a large number of pads as external connection terminals are arranged on the semiconductor chip 11 at a small pitch, lead tips of the inner lead portion can be arranged at the same pitch. This serves to accommodate an increased number of pins of the semiconductor chip 11.

[Second Embodiment]

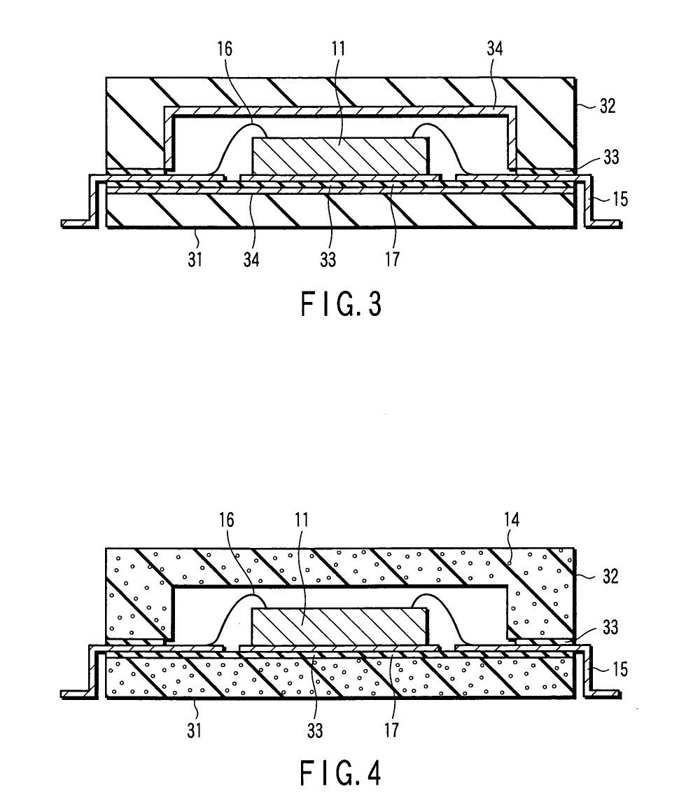

A second embodiment of the present invention will be described with reference to FIG. 3. This figure is a sectional view schematically showing that an MRAM is sealed in a ceramic package (enclosure). In the second embodiment, only differences from the first embodiment will be described. The description of the other points is omitted.

As shown in FIG. 3, the semiconductor chip 11, die-bonded on the die pad 17 of the lead frame 15, is sealed by a ceramic package. This ceramic package is formed of a ceramic base (base material) 31 and a ceramic cap (cap material) 32 joined together via sealing glass (sealing material) 33. Further, a magnetic film 34 is formed on a chip side surface of the ceramic base 31 and inside the ceramic cap 32 so as to surround the semiconductor chip 11. The Magnetic film 34 is formed of, for example, a ferrite (MFe₂O₄, where M=one of Mn, Fe, Co, Ni, Cu, Mg, and ZnLi_{0.5}Fe_{0.5}).

With this structure, in which the magnetic film 34 surrounds the magnetic element in the semiconductor chip 11, the magnetic film 34 absorbs most external leakage magnetic fields, that may cause malfunctions. Consequently, few external magnetic fields are applied to the magnetic element in the semiconductor chip 11, resulting in a high magnetic shielding effect. As a result, it is possible to provide a reliable MRAM product which can retain data appropriately and which does not malfunction.

In general, the ceramic cap 31 and the ceramic base 32 are often made of Al₂O₃. Here, Al₂O₃ is a metal oxide, and the ferrite film, which constitutes the magnetic film 34, is also a metal oxide. Furthermore, the metal oxide is characterized by its favorable adhesion at an interface. This eliminates the needs for adhesion layers or the like at the interfaces between the ceramic cap 32 and the magnetic film 34 and between the ceramic base 31 and the magnetic film 34. As a result, it is possible to provide an inexpensive MRAM product or the like which can be manufactured using a simple process.

[Variation 2]

Now, with reference to FIG. 4, description will be given of a variation of a semiconductor device according to the second embodiment. In this Variation 2, only differences from the second embodiment will be described. The other points are similar to those of the second embodiment. Thus, their description is omitted.

As shown in FIG. 4, in this Variation 2, rather than providing the magnetic film 34 as in the case with the second embodiment, the magnetic substance particles 14 are interspersed in the ceramic base 31 and the ceramic cap 32. The magnetic substance particles 14 are each shaped to be spherical. Further, as in the case with the first embodiment, the magnetic substance particles 14 interspersed in the ceramic base 31 and ceramic cap 32 amount to 1 wt % or more of the total weight of the ceramic base 31 and ceramic cap 32.

In this Variation 2, the diameter of each magnetic substance particle 14 need not necessarily be about 20 μm or less. In the above described first embodiment and its variation, the semiconductor chip 11 and the bonding wires 16 are buried in the package 13. Accordingly, if the magnetic grain is large-sized, defects may occur; a resin used to form the package 13 may be inappropriately injected or the bonding wires 16 may be cut.

However, in this Variation 2, the ceramic cap 32 serves to create a cavity around the semiconductor chip 11 and bonding wires 16. This avoids defects such as those described above, and the size of the magnetic substance particle 14 is not important provided that it is shaped to be spherical. Accordingly, the magnetic substance particles 14 may have different diameters. This reduces manufacturing costs.

By thus premixing the magnetic substance particles 14 in a ceramic material (for example, slurry) for the ceramic base 31 and the ceramic cap 32, the magnetic substance particles 14 can be interspersed in the ceramic base 31 and the ceramic cap 32 as in the case with the first embodiment. This makes it unnecessary to complicate the manufacturing process. The MRAM can thus be manufactured using a process similar to a typical manufacturing method. Therefore, an inexpensive and reliable MRAM product can be accomplished.

The ceramic material may be composed of a material other than Al₂O₃, such as AlN or BeO. Further, the magnetic substance particles 14 interspersed in the ceramic base 31 and ceramic cap 32 may be composed of an oxide magnetic substance other than a ferrite, such as a spinel oxide magnetic substance (for example, chromite), a garnet oxide magnetic substance, or a perovskite oxide magnetic substance.

[Variation 3]

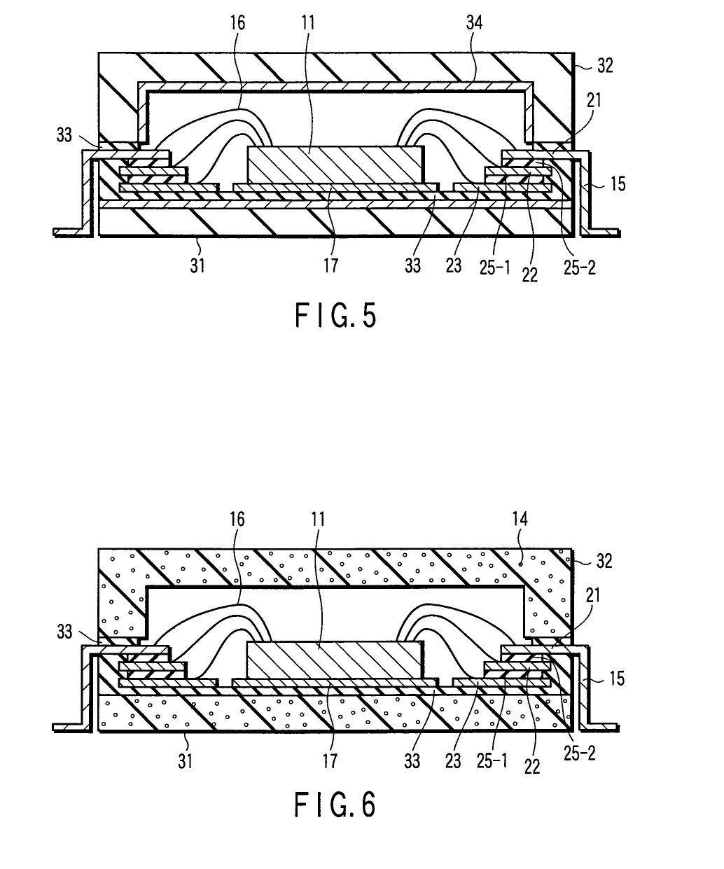

Now, another variation of the second embodiment will be described with reference to FIGS. 5 and 6. In this Variation 3, only differences from the second embodiment and Variation 2 will be described. The description of the other points is omitted.

The variation shown in FIG. 5 is the configuration shown in FIG. 3 in which the inner lead portion has a stacked structure as shown in FIG. 2. Further, the variation shown in FIG. 6 is the configuration shown in FIG. 4 in which the inner lead portion has a stacked structure as shown in FIG. 2.

When the inner lead portion inside the ceramic cap 31 is multilayered, the substantial connection pitch (width) of the semiconductor chip 11 can be increased. This serves to sufficiently accommodate an increase in the number of pads of the semiconductor chip 11 or a decrease in the pitch of the semiconductor chip 11.

In the description of the first and second embodiments and their variations, the magnetic substance particle 14 need not necessarily be exactly spherical. That is, the magnetic substance particle 14 may have any shape as long as its magnetic shape anisotropy does not contribute to weakening the magnetic shield effect. In other words, the magnetic substance particle 14 need not be shaped to be exactly spherical provided that it can produce a sufficient magnetic shield effect.

In the description of the above embodiments and their variations, the MRAM is taken as an example. However, the present invention is also applicable to other semiconductor devices having magnetic elements.

Furthermore, in the example described above, the semiconductor chip is mounted on the lead frame. However, even if the semiconductor chip is mounted on, for example, a TAB tape, similar operations and effects are of course obtained by interspersing the magnetic substance particles in a potting resin.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor chip comprising a magnetic element;
an enclosure which seals the magnetic chip; and
substantially spherical magnetic substance particles which are interspersed in the enclosure.

2. A semiconductor device comprising:
a semiconductor chip comprising a magnetic element;
an enclosure which seals the magnetic chip and which has a base material and a cap material joined together via a sealing material; and
a magnetic film provided on a chip side surface of the base material and on an inner surface of the cap material so as to surround the semiconductor chip.

3. The semiconductor device according to claim 1, wherein the enclosure is a plastic package or a ceramic package.

4. The semiconductor device according to claim 2, wherein the enclosure is a ceramic package.

5. The semiconductor device according to claim 3, wherein the plastic package contains an epoxy resin or a silicone resin.

6. The semiconductor device according to claim 3, wherein the ceramic package contains at least one of Al₂O₃, AlN, and BeO.

7. The semiconductor device according to claim 4, wherein the ceramic package contains at least one of Al₂O₃, AlN, and BeO.

8. The semiconductor device according to claim 1, further comprising a lead frame, and
wherein the lead frame has:
a die pad on which the semiconductor chip is mounted;
an inner lead portion sealed by the enclosure; and
an outer lead portion led out of the enclosure.

9. The semiconductor device according to claim 2, further comprising a lead frame, and
wherein the lead frame has:
a die pad on which the semiconductor chip is mounted;
an inner lead portion sealed by the enclosure; and
an outer lead portion led out of the enclosure.

10. The semiconductor device according to claim 8, wherein the inner lead portion of the lead frame has a stacked structure in which a plurality of conductive layers are stacked via insulating layers, and the plurality of conductive layers are electrically connected to corresponding external connection electrodes on the semiconductor chip by bonding wires.

11. The semiconductor device according to claim 9, wherein the inner lead portion of the lead frame has a stacked structure in which a plurality of conductive layers are stacked via insulating layers, and the plurality of conductive layers are electrically connected to corresponding external connection electrodes on the semiconductor chip by bonding wires.

12. The semiconductor device according to claim 1, wherein the magnetic element is a tunnel magneto-resistance element.

13. The semiconductor device according to claim 2, wherein the magnetic element is a tunnel magneto-resistance element.

14. The semiconductor device according to claim 1, wherein each magnetic substance particle contains at least one of an insulator, an oxide, and a ferrite.

15. The semiconductor device according to claim 1, wherein each magnetic substance particle has a diameter of 20 μm or less.

16. The semiconductor device according to claim 1, wherein the magnetic substance particles occupy 1 wt % or more of the enclosure.
